(19) United States
(12) Patent Application Publication
(10) Pub. No.: US 2025/0201589 A1
(43) Pub. Date: Jun. 19, 2025

(54) METHOD FOR CLEANING SEMICONDUCTOR WAFERS IN A CLEANING LINE

(71) Applicant: Siltronic AG, Munich (DE)

(72) Inventor: Bertram MÖCKEL, Freiberg (DE)

(21) Appl. No.: 18/848,950

(22) PCT Filed: Mar. 8, 2023
(86) PCT No.: PCT/EP2023/055861

§ 371 Date: Sep. 20, 2024

(30) Foreign Application Priority Data
Mar. 24, 2022 (EP) 22164084.0

(51) Int. Cl. H01L 21/67; B25J 11/00; H01L 21/02

(52) U.S. Cl. CPC H01L 21/6704; B25J 11/0095; H01L 21/02057

(57) ABSTRACT

A method cleans semiconductor wafers in a cleaning line, which includes at least two cleaning modules, and at least one gripping system, which includes two adjacent manipulators each configured to move over at least one of the cleaning modules. The method includes: in the cleaning modules, successively treating a vertically oriented semiconductor wafer during cleaning steps with a liquid of a respective cleaning step; and moving a first manipulator, of the two adjacent manipulators, through a slot in a cover of a first cleaning module, of the cleaning modules, to load or pick up the vertically oriented semiconductor wafer, while a second manipulator, of the two adjacent manipulators, is arranged to remain between the slot in the cover of the first cleaning module and a slot in a cover of a second cleaning module of the cleaning modules.

### CROSS REFERENCE TO RELATED APPLICATIONS

This application is a U.S. National Phase application under 35 U.S.C. § 371 of International Application No. PCT/EP2023/055861, filed on Mar. 8, 2023, and claims benefit to European Patent Application No. EP 22164084.0, filed on Mar. 24, 2022. The International Application was published in German on Sep. 28, 2023 as WO 2023/180070 A1 under PCT Article 21(2).

### FIELD

The present disclosure relates to a method for cleaning semiconductor wafers in a cleaning line.

### BACKGROUND

US2003 0 200 988 A1 describes a modular substrate cleaning system by means of which a plurality of semiconductor wafers can be subjected simultaneously in an indexed sequence to individual wafer cleaning in successive cleaning modules of a cleaning line.

The disadvantage of this is its low flexibility.

US2006 0 254 715 A1 describes a method by means of which a semiconductor wafer is transported between successively arranged cleaning modules of a cleaning line in order to subject it to individual wafer cleaning in each of the cleaning modules. In the course of this, at least one of two manipulators is lowered into the cleaning module in order to load or pick up the semiconductor wafer.

The disadvantage of this is that cross-contamination can occur, endangering the success of the cleaning process.

### SUMMARY

In an embodiment, the present disclosure provides a method for cleaning semiconductor wafers in a cleaning line, which includes at least two cleaning modules, and at least one gripping system, which includes two adjacent manipulators each configured to move over at least one of the cleaning modules. The method includes: in the cleaning modules, successively treating a vertically oriented semiconductor wafer during cleaning steps with a liquid of a respective cleaning step; and moving a first manipulator, of the two adjacent manipulators, through a slot in a cover of a first cleaning module, of the cleaning modules, to load or pick up the vertically oriented semiconductor wafer, while a second manipulator, of the two adjacent manipulators, is arranged to remain between the slot in the cover of the first cleaning module and a slot in a cover of a second cleaning module of the cleaning modules.

### BRIEF DESCRIPTION OF THE DRAWING

Subject matter of the present disclosure will be described in even greater detail below based on the exemplary FIGURE. All features described and/or illustrated herein can be used alone or combined in different combinations. The features and advantages of various embodiments will become apparent by reading the following detailed description with reference to the attached drawing, which illustrates the following:

The FIGURE shows a plan view of a polishing station with a connected cleaning station, which is suitable for carrying out the method of the present disclosure.

### DETAILED DESCRIPTION

Aspects of the present disclosure increase the efficiency of the cleaning of a semiconductor wafer in a cleaning line, and avoid a situation where the semiconductor wafer is contaminated during handling in the course of cleaning.

In an implementation of aspects of the present disclosure, a method is provided for cleaning semiconductor wafers in a cleaning line which comprises at least two cleaning modules, in which a vertically oriented semiconductor wafer is treated successively during cleaning steps with a liquid of the respective cleaning step, wherein at least one gripping system, which comprises two adjacent manipulators, is moved over one of the cleaning modules, and the one manipulator is moved through a slot in a cover of the one cleaning module in order to load or pick up the semiconductor wafer. The method may be characterized in that, the other manipulator is arranged between the slot in the cover of the one cleaning module and a slot in a cover of the other cleaning module.

The arrangement of the manipulators avoids a situation where, while the one manipulator is being moved over a cleaning module and this manipulator is being lowered into the cleaning module, liquid can cause cross-contamination if it drips from the other manipulator or from a semiconductor wafer which is being held by the other manipulator.

The cleaning line comprises at least one gripping system, on which two manipulators are secured. The two manipulators are arranged at a fixed distance from one another. At least one further gripping system with one or two manipulators is preferably present. A further gripping system with a manipulator is preferably used in order to transport a semiconductor wafer to a dryer after the last cleaning step.

The method is preferably used to clean a semiconductor wafer after polishing by means of CMP (chemical mechanical polishing). After CMP, the semiconductor wafer passes through a sequence of cleaning steps. During each of the cleaning steps, the semiconductor wafer is subjected to individual wafer treatment with a liquid cleaning agent in a cleaning module. During this process, the semiconductor wafer is treated with the cleaning agent while vertical. If necessary, it stands on rolls and is rotated about its center. The order of the sequence may, but need not, correspond to the order of the arrangement of the cleaning modules. Each cleaning module is designed either for carrying out bath cleaning, spray cleaning, brush cleaning or a combination of spray cleaning and brush cleaning. During bath cleaning, the semiconductor wafer is dipped into the cleaning agent, during spray cleaning, the front and rear sides of the semiconductor wafer are sprayed with the cleaning agent, and, during brush cleaning, the cleaning agent is distributed on the front and rear sides of the semiconductor wafer by means of rotating brushes. The cleaning liquid can be fed in via the rolls or via separate spray nozzles. Cleaning in the cleaning bath can be assisted by irradiation with megasonic waves.

Each cleaning module of the cleaning line is provided with a cover, in which a slot is incorporated. To load a semiconductor wafer in one of the cleaning modules or to remove a semiconductor wafer from one of the cleaning modules, one of two manipulators of a gripping system is moved through the slot into this one cleaning module. In order to avoid cross-contamination by dripping liquid, the other manipulator of the gripping system remains, during this process, in a position which makes it impossible for liquid dripping from the other manipulator or a semiconductor wafer held by it to fall through the slot in the cover into this one cleaning module. This position is an arrangement of the second manipulator between the slot in the cover of this one cleaning module and the slot in the cover of an adjacent cleaning module. The other manipulator is preferably arranged above the cover of this one cleaning module but not above the slot in the cover of this one cleaning module.

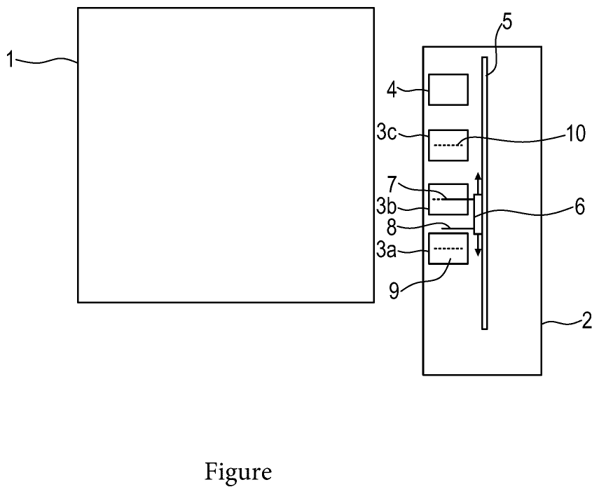

FIG. 1 shows, schematically, the arrangement of a polishing station 1 and a cleaning station 2, which comprises three cleaning modules 3a to 3c. These cleaning modules and a dryer 4 are part of a cleaning line in which a semiconductor wafer is cleaned and dried in the polishing station 1 after CMP has been completed. The polishing station comprises at least one polishing head, which presses a semiconductor wafer to be polished against a polishing cloth during polishing. Robots, which transport a polished semiconductor wafer from the polishing station to the cleaning station, and devices for the intermediate storage of the semiconductor wafer are not illustrated either.

The cleaning line comprises a guide 5 for a gripping system 6 with two manipulators 7 and 8 secured thereon. A semiconductor wafer to be cleaned is held by one of the two manipulators 7, 8 and is lowered from a position above one of the cleaning modules 3a to 3c into the cleaning module and loaded in the cleaning module. A semiconductor wafer cleaned in one of the cleaning modules is picked up in the cleaning module by one of the two manipulators 7, 8 and lifted out of the cleaning module. A further gripping system with a manipulator is preferably present, and this transports a semiconductor wafer to the dryer 4 after the last cleaning step.

Each of the cleaning modules 3a to 3c has a cover 9 and each of these covers has a slot 10, which allows the manipulators 7 and 8 access to the respective cleaning module.

If one of the two manipulators 7, 8 loads a semiconductor wafer in a cleaning module or lifts it out of a cleaning module, the other manipulator assumes a position between the slot 10 in the cover of this cleaning module and the slot 10 in the cover of an adjacent cleaning module. In this situation, drops of liquid, which may be from the other manipulator or a semiconductor wafer held by the other manipulator, cannot fall through the slot in the cover of the cleaning module in which the one manipulator is active.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS USED

1 polishing station
2 cleaning station
3a cleaning module
3b cleaning module
3c cleaning module
4 dryer
5 guide
6 gripping system
7 manipulator
8 manipulator
9 cover
10 slot

1: A method for cleaning semiconductor wafers in a cleaning line, which comprises at least two cleaning modules, and at least one gripping system, which comprises two adjacent manipulators each configured to move over at least one of the cleaning modules, the method comprising:
in the cleaning modules, successively treating a vertically oriented semiconductor wafer during cleaning steps with a liquid of a respective cleaning step;
moving a first manipulator, of the two adjacent manipulators, through a slot in a cover of a first cleaning module, of the cleaning modules, to load or pick up the vertically oriented semiconductor wafer, while a second manipulator, of the two adjacent manipulators, is arranged to remain between the slot in the cover of the first cleaning module and a slot in a cover of a second cleaning module of the cleaning modules.

2: The method according to claim 1, wherein the cleaning line comprises three cleaning modules.

3: The method according to claim 1, wherein the second manipulator is arranged above the cover of the first cleaning module but not above the slot in the cover of the second cleaning module.

4: A system for cleaning semiconductor wafers in a cleaning line, the system comprising:
two cleaning modules each comprising a cover with a slot, configured to treat successively a vertically oriented semiconductor wafer during cleaning steps with a liquid of a respective cleaning step,
at least one gripping system, which comprises two adjacent manipulators, each of which being configured to be moved over one of the cleaning modules,
wherein a first manipulator is configured to be moved through the slot in the cover of a first cleaning module in order to load or pick up a semiconductor wafer,
wherein a second manipulator is configured to remain between the slot in the cover of the first cleaning module and the slot in the cover of the second cleaning module while the first manipulator is being moved, and
wherein the two adjacent manipulators are the first manipulator and the second manipulator, and the two cleaning modules are the first cleaning module and the second cleaning module.
